(19) United States
(12) Patent Application Publication
(10) Pub. No.: US 2019/0198630 A1
(43) Pub. Date: Jun. 27, 2019

(54) Managing Gate Coupling For Memory Devices

(71) Applicant: Macronix International Co., Ltd., Hsinchu (TW)

(72) Inventors: Chien-Ying Lee, New Taipei (TW); Chih-Hsiung Lee, Hsinchu (TW); Tzung-Ting Han, Hsinchu (TW)

(73) Assignee: Macronix International Co., Ltd., Hsinchu (TW)

(21) Appl. No.: 15/849,971

(22) Filed: Dec. 21, 2017

(51) Int. Cl. H01L 29/423; H01L 21/28; H01L 21/3213; H01L 29/66; H01L 29/06; H01L 29/788; H01L 27/11521

(52) U.S. Cl. CPC H01L 29/42324; H01L 21/28273; H01L 21/32137; H01L 21/32139; H01L 27/11521; H01L 29/0649; H01L 29/42376; H01L 29/7883; H01L 29/66825

(57) ABSTRACT

Methods of managing gate coupling for semiconductor devices, e.g., non-volatile memory devices, are provided. The methods include: providing a conductive layer on a semiconductor substrate, the conductive layer including a lower conductive layer and an upper conductive layer, the lower conductive layer including a first material and the upper conductive layer including a second material having at least one property different from the first material, forming a protective pattern on the conductive layer, and etching through the conductive layer to obtain individual separated gates by controlling an etching process such that the first material has a higher etching rate than the second material during the etching process, each of the gates including an upper gate and a lower gate, the lower gate having a smaller width than the upper gate after the etching process.

### BACKGROUND

During manufacturing a memory device, e.g., a non-volatile memory device, an etching process can cause a variation of effective field height (EFH) among different memory transistors, which may affect one or more properties of the memory device such as gate coupling ratio (GCR) and further a performance of the memory device.

### SUMMARY

The present disclosure describes methods of managing gate coupling, e.g., coupling between floating gate and control gate in transistors, for memory devices or systems, e.g., a non-volatile memory device, and the memory devices or systems provided by such methods.

One aspect of the present disclosure features a method of fabricating a semiconductor device, including: providing a conductive layer on a semiconductor substrate, the conductive layer including a lower conductive layer and an upper conductive layer, the lower conductive layer including a first material and the upper conductive layer including a second material having at least one property different from the first material; forming a protective pattern on the conductive layer; and etching through the conductive layer to obtain individual separated gates by controlling an etching process such that the first material has a higher etching rate than the second material during the etching process, each of the gates including an upper gate and a lower gate, the lower gate having a smaller width than the upper gate after the etching process.

The lower gate and the upper gate can have a same center line. The first material can have a smaller grain size than the second material. In some examples, the first material includes polysilicon with a grain size less than 10 nm, and the second material includes polysilicon with a grain size in a range between 10 nm and 50 nm.

In some cases, providing the conductive layer on the semiconductor substrate can include forming a tunnel insulating layer on the semiconductor substrate. In some cases, forming the protective pattern on the conductive layer includes using self-aligned double patterning (SADP). In some cases, forming the protective pattern on the conductive layer includes: forming one or more layers as a hard mask on the conductive layer; forming a second protective pattern on the one or more layers; and etching through the one or more layers to obtain a hard mask pattern as the protective pattern for the conductive layer.

The etching process can be part of a shallow trench isolation (STI) etching process for fabricating the semiconductor device. In some cases, controlling the etching process can include controlling a flow rate of etching gas. In some cases, controlling the etching process to etch the conductive layer includes etching through the conductive layer into the semiconductor substrate to form trenches between adjacent gates.

The method can further include forming an isolation layer on the protective pattern and in the trenches. A material of the isolation layer can include spin-on dielectric (SOD) material. The method can further include etching the isolation layer to obtain gaps between adjacent gates of the individual gates, where at least one of the gaps has a bottom surface between lower surfaces of an upper gate and a lower gate of one of the individual gates.

The method can further include forming a dielectric layer on the individual gates and the isolation layer in the gaps, where a space between sidewalls of the lower gate of the one of the individual gates and the dielectric layer is filled with the isolation layer. The method can further include forming a second conductive layer on the dielectric layer as a second gate electrode.

Another aspect of the present disclosure features a semiconductor memory device including: a semiconductor substrate including active regions protruding therefrom, adjacent active regions defining trenches therebetween; an isolation layer formed on the semiconductor substrate and in the trenches; floating gates formed on corresponding active regions, each floating gate having a lower floating gate and an upper floating gate that are sequentially stacked, the lower floating gate having a smaller width than the upper floating gate and a substantially same center line as the upper floating gate; an inter-gate dielectric layer on top surfaces of the floating gates and on the isolation layer, the inter-gate dielectric layer defining gaps between adjacent floating gates, and a control gate electrode on top of the floating gates and in the gaps of the dielectric layer. At least one of the gaps has a bottom surface being between a top surface and a bottom surface of the lower floating gate of one of the floating gates, and a space between sidewalls of the lower floating gate and the inter-gate dielectric layer in the gap is filled with a material of the isolation layer.

The lower floating gate and the upper floating gate of each of the floating gates can be self-aligned with the corresponding active region. A gate coupling ratio between the one of the floating gates and the control gate electrode can be partially based on a width of the filled-in material of the isolation layer in the space. The semiconductor memory device can further include a tunnel insulating layer positioned between each of the floating gates and the corresponding active region.

A third aspect of the present disclosure features a method of fabricating a semiconductor device including: providing a physical layer on a semiconductor substrate, the layer having a lower layer and an upper layer that are sequentially stacked, the lower layer including a first material and the upper layer including a second material that has at least one property different from the first material; forming a protective pattern on the layer; and controlling an etching process to etch the layer, such that the first material has a different etching rate than the second material during the etching process and the lower layer has a different dimension than the upper layer after the etching process, the lower layer and the upper layer having a same center line.

A fourth aspect of the present disclosure features a method of fabricating a semiconductor memory device, including: forming a tunnel insulating layer on a semiconductor substrate; forming a floating gate layer on the tunnel insulating layer, the floating gate layer including a lower gate layer and an upper gate layer; forming a hard mask pattern on the floating gate layer; etching through the floating gate layer and the tunnel insulating layer into the semiconductor substrate to form separated floating gates by controlling an etching process such that the lower gate layer has a higher etching rate than the upper gate layer during the etching process, each of the floating gates including an upper floating gate from the upper gate layer and a lower floating gate from the lower gate layer, the lower floating gate having a smaller width than the upper floating gate after the etching process; forming an isolation layer on the floating gates and in trenches defined between adjacent floating gates; etching the isolation layer to form gaps between adjacent floating gates; forming an inter-gate dielectric layer on the floating gates; and forming a control gate electrode on the inter-gate dielectric layer crossing over the floating gates. At least one of the gaps has a bottom surface between a top surface and a bottom surface a lower floating gate of one of the floating gates, and a space between sidewalls of the lower floating gate of the one of the floating gates and the inter-gate dielectric layer is filled with the material of the insulation layer.

The details of one or more disclosed implementations are set forth in the accompanying drawings and the description below. Other features, aspects, and advantages will become apparent from the description, the drawings and the claims.

### BRIEF DESCRIPTION OF THE DRAWINGS

FIG. 1A illustrates an example of a system including a memory, according to one or more implementations.

FIG. 1B illustrates an example memory block in the memory of FIG. 1A, according to one or more implementations.

FIG. 1C illustrates example memory cells in the memory of FIG. 1A, according to one or more implementations.

FIG. 2 is a cross-sectional view of an example non-volatile memory device illustrating exemplary coupling between floating gate and control gate.

FIGS. 3A-3G are cross-sectional views illustrating process steps of a method of fabricating a non-volatile memory device, according to one or more implementations.

FIG. 4 is a cross-sectional view of an individual region in FIG. 3C after etching through floating gate, according to one or more implementations.

FIGS. 5A-5B are cross-sectional views of an example non-volatile memory device illustrating exemplary coupling between floating gate and control gate, according to one or more implementations.

FIG. 6 shows an example process of fabricating a semiconductor device, according to one or more implementations.

### DETAILED DESCRIPTION

Implementations of the present disclosure provide methods of managing gate coupling in a memory device by using different materials for different portions of floating gate to generate different critical dimensions (CDs) for the different portions during etching. After the etching, insulating material, e.g., spin-on dielectric (SOD), can fill spaces caused by the different CDs of the different portions of floating gate. The insulating material filled in these spaces can result in less gate coupling between control gate and floating gate to thereby better control gate coupling ratio (GCR) among different transistors in the memory device. This technology can reduce an effect of large effective field height (EFH) variation among the transistors thereby improving a uniformity of the GCR and thus a performance of the memory device.

This technology can use different films with different etching characteristics to get different layers with different sizes for any desired purpose. For example, it is applicable to a memory array and/or periphery for any coupling issue or boundary charge trap issue. This technology is also applicable to fabrication of any suitable non-volatile memory system, e.g., NAND flash memory, NOR flash memory, AND flash memory, phase-change memory (PCM), or others, or any other semiconductor devices or systems, e.g., logic devices. For illustration purpose only, the following description is directed to managing gate coupling for non-volatile memory devices.

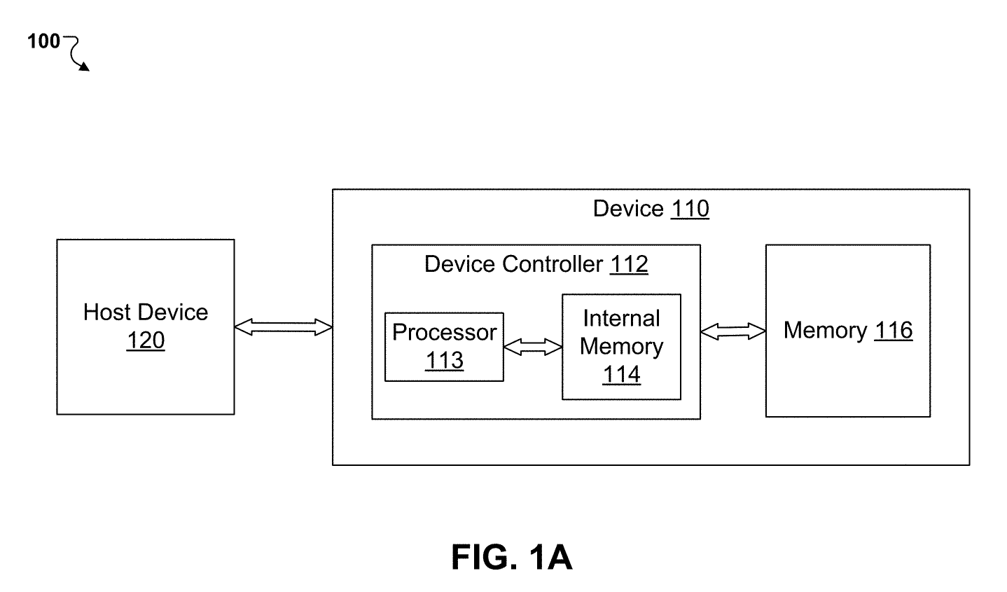

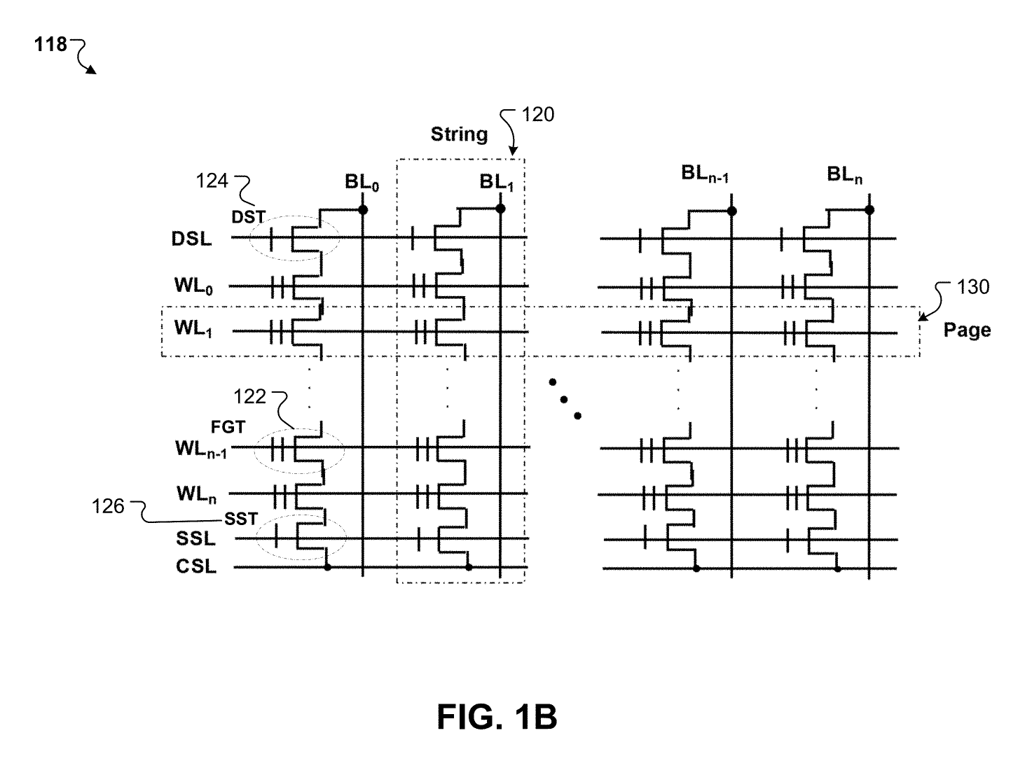

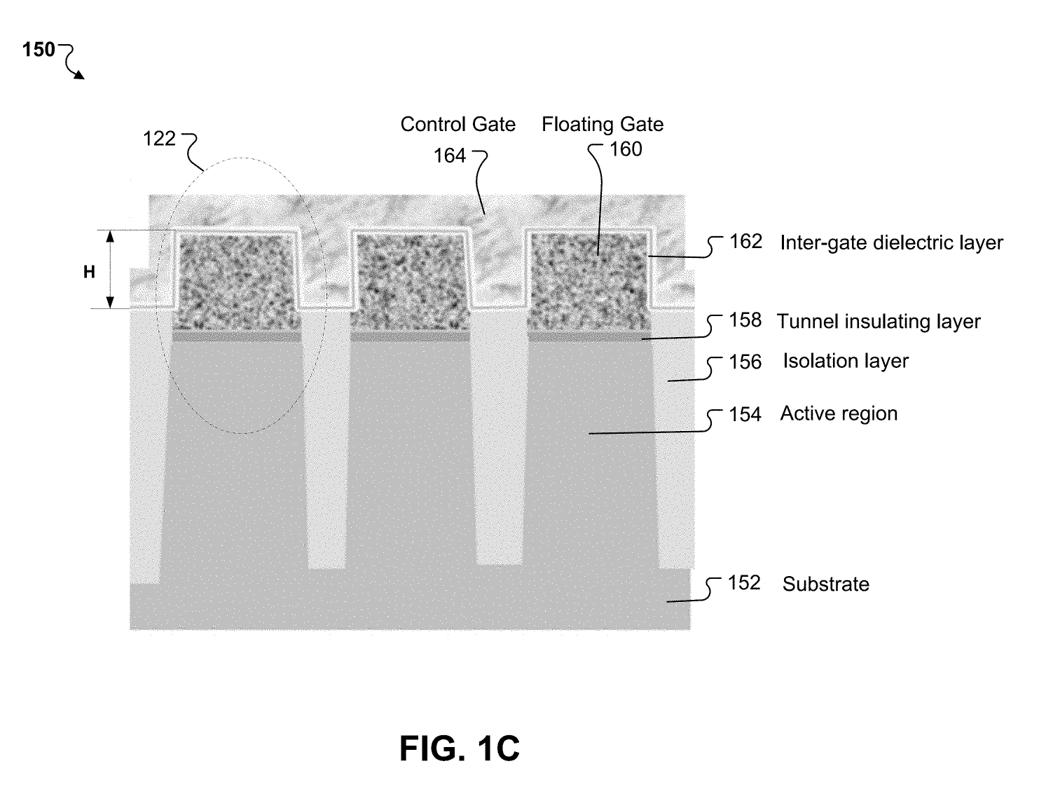

FIG. 1A illustrates an example of a system 100. The system 100 includes a device 110 and a host device 120. The device 110 includes a device controller 112 and a memory 116. The device controller 112 includes a processor 113 and an internal memory 114.

In some implementations, the device 110 is a storage device. For example, the device 110 can be an embedded multimedia card (eMMC), a secure digital (SD) card, a solid-state drive (SSD), or some other suitable storage. In some implementations, the device 110 is a smart watch, a digital camera or a media player. In some implementations, the device 110 is a client device coupled to a host device 120. For example, the device 110 is an SD card in a digital camera or a media player that is the host device 120.

The device controller 112 is a general-purpose microprocessor, or an application-specific microcontroller. In some implementations, the device controller 112 is a memory controller for the device 110. The following sections describe the various techniques based on implementations in which the device controller 112 is a memory controller. However, the techniques described in the following sections are also applicable in implementations in which the device controller 112 is another type of controller that is different from a memory controller.

The processor 113 is configured to execute instructions and process data. The instructions include firmware instructions and/or other program instructions that are stored as firmware code and/or other program code, respectively, in the secondary memory. The data includes program data corresponding to the firmware and/or other programs executed by the processor, among other suitable data. In some implementations, the processor 113 is a general-purpose microprocessor, or an application-specific microcontroller. The processor 113 is also referred to as a central processing unit (CPU).

The processor 113 accesses instructions and data from the internal memory 114. In some implementations, the internal memory 114 is a Static Random Access Memory (SRAM) or a Dynamic Random Access Memory (DRAM). For example, in some implementations, when the device 110 is an eMMC, an SD card or a smart watch, the internal memory 114 is an SRAM. In some implementations, when the device 110 is a digital camera or a media player, the internal memory 114 is DRAM.

In some implementations, the internal memory is a cache memory that is included in the device controller 112, as shown in FIG. 1A. The internal memory 114 stores instruction codes, which correspond to the instructions executed by the processor 113, and/or the data that requested by the processor 113 during runtime.

The device controller 112 transfers the instruction code and/or the data from the memory 116 to the internal memory 114. In some implementations, the memory 116 is a non-volatile memory configured for long-term storage of instructions and/or data, e.g., a NAND flash memory device, or some other suitable non-volatile memory device. In implementations where the memory 116 is NAND flash memory, the device 110 is a flash memory device, e.g., a flash memory card, and the device controller 112 is a NAND flash controller. For example, in some implementations, when the device 110 is an eMMC or an SD card, the memory 116 is a NAND flash; in some implementations, when the device 110 is a digital camera, the memory 116 is an SD card; and in some implementations, when the device 110 is a media player, the memory 116 is a hard disk. For illustration purposes only, the following description uses a NAND flash memory as an example of the memory 116.

FIG. 1B illustrates an example configuration of a block 118 of the memory 116. The block 118 includes a number of memory cells 122 that are coupled in series to column bit lines BL₀, BL₁, . . . , BLₙ₋₁, and BLₙ to form a plurality of cell strings 120, and to row word lines WL₀, WL₁, . . . , WLₙ₋₁, and WLₙ to form a plurality of cell pages 130.

In some implementations, a cell string 120 includes a drain select transistor (DST) 124, a plurality of memory cells 122, and a source select transistor (SST) 126, which are all connected in series. A drain of the DST 124 is connected to a bit line BL, and its source is connected to a drain of the memory cell 122. A gate of the DST 124 is connected to a drain select line (DSL). Gates of the DSTs in different strings are also connected to the same DSL. Gates of the memory cells 122 are respectively connected to word lines WL₀, WL₁, . . . , WLₙ₋₁, WLₙ. A drain of the SST 126 is connected to a source of the memory cells 122, and its drain is connected to a common source line (CSL). A gate of the SST 126 is connected to a source select line (SSL). Gates of the SSTs in different strings are also connected to the same SSL. The DST 124 and the SST 126 can be metal-oxide-semiconductor (MOS) transistors, and the memory cells 122 can be floating gate transistors (FGT).

FIG. 1C shows a cross sectional view 150 of example memory cells 122 in the memory 116, where the memory cells 122 are floating gate transistors. The memory cells 122 are formed on a semiconductor substrate 152. The substrate 152 includes a plurality of active regions 154 protruded therefrom. Sidewalls (or side walls) of adjacent active regions define a trench therebetween. An isolation layer 156 fills in the trenches and extends along the sidewalls of the active regions 154.

Each floating gate 160 is positioned on top of a respective active region 154 and is insulated from the active region 154 by a tunnel insulating layer 158, e.g., a tunnel oxide layer. The floating gate 160 can be self-aligned with the active region 154. For example, the floating gate 160 and the active region 154 can be fabricated in the same process and no extra step is needed to align the floating gate 160 and the active region 154. After the fabrication, a center line of the floating gate 160 can be automatically aligned with a center line of the active region 154, e.g., the two center lines are the same. As discussed with further details below, the floating gate 160 can include multiple parts, such as a lower floating gate and an upper floating gate that are sequentially stacked together. The lower floating gate can be made of a material having a different property from a material of the upper floating gate, such that the lower floating gate can have different etching characteristics than the upper floating gate. For example, the lower floating gate and the upper floating gate can be made of polysilicon (polycrystalline silicon) and the lower floating gate can include polysilicon with a smaller grain size than the upper floating gate.

A control gate electrode 164 is positioned on top of the floating gates 160 and acts as a control gate for each memory cell 122. The floating gates 160 are insulated from the control gate electrode 164 by an inter-gate dielectric layer 162. A bottom surface of the inter-gate dielectric layer 162 (or a top surface of the isolation layer 156) is lower than a top surface of the floating gate 160 and higher than a top surface of the tunnel insulating layer 158. In a particular example, the top surface of the isolation layer 156 is formed to be at a substantially similar level as a top surface of a lower floating gate of the floating gate 160. The inter-gate dielectric layer 162 defines gaps between adjacent floating gates 160, where the control gate electrode 164 fills in the gaps.

The floating gate 160 can be electrically coupled with the control gate electrode 164 along a contour profile of the inter-gate dielectric layer 162. A height H of the gap can be defined as a vertical distance between a top surface of the floating gate 160 and a bottom surface of the inter-gate dielectric layer 162 at the bottom of the gap. In some cases, the coupling between the floating gate 160 and the control gate electrode 164 occurs along the height H, and the height H can be referred to as effective field height (EFH).

Impurity regions, e.g., source/drain regions, can be formed in the active regions 154. As illustrated in FIG. 1C, a memory cell 122, e.g., a floating gate transistor, can be provided at intersections between the control gate electrode 164 and a respective active region 154. For example, the memory cell 122 is provided at an overlap between the control gate electrode 164 and the respective active region 154 and includes the control gate 164, the inter-gate dielectric layer 162, a respective floating gate 160, a tunnel-insulating layer 158, and the respective active region 154.

Electrons are injected into the floating gate 160 from a channel and are injected into the channel from the floating gate 160, e.g., by a Fowler-Nordheim (F-N) tunneling current, thereby programming and erasing data in a memory cell 122 of the non-volatile memory 116. When the electrons are injected into the floating gate 160, a potential energy of the floating gate 160 is changed, and thus a threshold voltage of a transistor is varied in accordance with the potential energy change. As a result, data are programmed into the memory cell 122 of the non-volatile memory 116. When the F-N tunneling current flows across the tunnel insulating layer 158, the electrons in the floating gate 160 are extracted into the channel, thereby erasing the data in the memory cell 122 of the non-volatile memory 116.

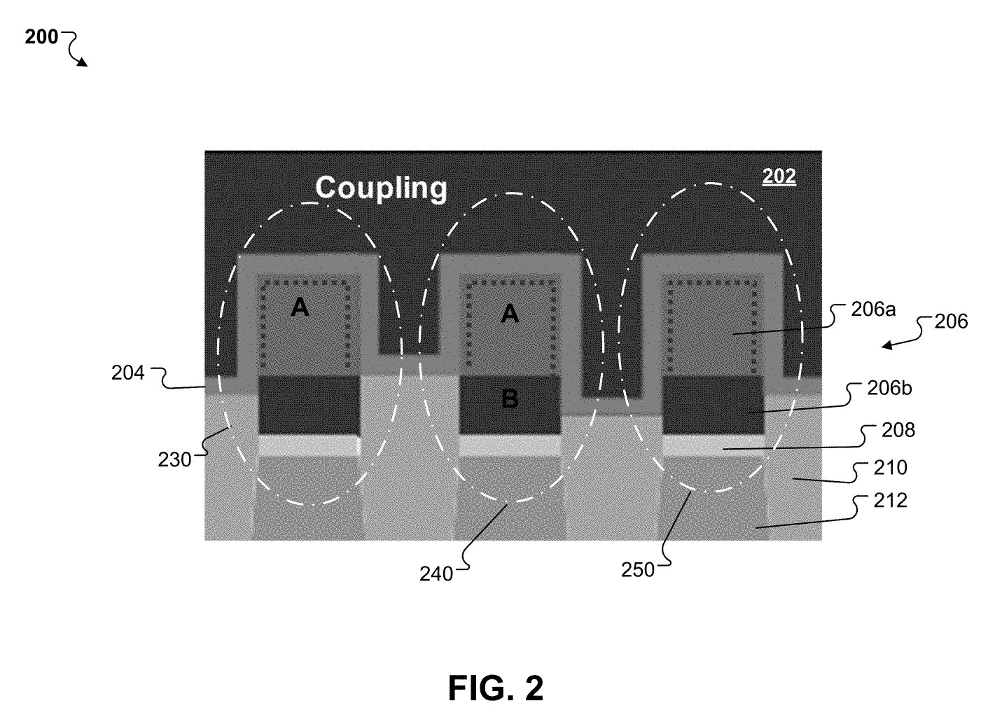

The non-volatile memory 116 can be operated at a time when a control gate voltage, which is a voltage applied to the control gate 164 from a power source, is applied to the floating gate 160. A voltage on the floating gate can be referred to as a floating gate voltage. Accordingly, a ratio of the floating gate voltage with respect to the control gate voltage has an effect on operation characteristics of the non-volatile memory 116. The ratio can be related to a gate-coupling ratio (GCR) defined as a ratio of a capacitance between control gate and floating gate and a capacitance of floating gate, as discussed in further detail with respect to FIG. 2.

In some cases, the gap height H may vary among the gaps defined by the inter-gate dielectric layer, e.g., due to fabrication instability or material defects. The variation of the gap height H causes a variation of EFH, which can affect the coupling between the floating gate 160 and the control gate 164 to cause non-uniformity of GCR. Accordingly, a programming voltage, e.g., the control gate voltage, can be hard to control.

FIG. 2 is a cross-sectional view 200 of a non-volatile memory device illustrating coupling between floating gate and control gate. The non-volatile memory device can be similar to the non-volatile memory 116 of FIG. 1C. A memory cell of the non-volatile memory device includes a control gate 202, an inter-gate dielectric layer 204, a floating gate 206, a tunnel insulating layer 208, an isolation layer 210, and an active region 212. As noted above, the floating gate 206 can include an upper floating gate 206a and a lower floating gate 206b that are sequentially stacked together.

The floating gate 206 can be electrically coupled with the control gate 202 along a contour profile of the inter-gate dielectric layer 204. As noted above, gaps defined by the inter-gate dielectric layer 204 and between adjacent floating gates can have varying heights, which can affect coupling between the floating gate and the control gate.

In some cases, as illustrated in FIG. 2, in memory cell 230, a bottom surface of the inter-gate dielectric layer 204 is no lower than (higher than or identical to) a top surface of the lower floating gate 206b, the coupling occurs between the upper floating gate 206a and the control gate 202, and a gate coupling ratio can be determined by a coupling area A between the upper floating gate 206a and the control gate 202.

In some cases, as illustrated in FIG. 2, in memory cell 240 or memory cell 250, a bottom surface of the inter-gate dielectric layer 204 is lower than a top surface of the lower floating gate 206b, and higher than a top surface of the tunnel insulating layer 208. The coupling occurs between the upper floating gate 206a and the control gate 202 and between the lower floating gate 206b and the coupling gate 202. Accordingly, a gate coupling ratio can be determined by a coupling area A between the upper floating gate 206a and the control gate 202, and a coupling area B between the lower floating gate 206b and the control gate 202. In some cases, different memory cells, e.g., memory cells 240 and 250, in the non-volatile memory can have different coupling areas B that depend on heights of the gaps adjacent the memory cells.

In some implementations, the gate coupling ratio (GCR) can be defined as a ratio of a capacitance between control gate and floating gate and a capacitance of floating gate, as follows:

GCR=C(CG to FG)/C(FG) (1).

The floating gates of the non-volatile memory device can have a substantially same size, and C(FG) can be a constant for the floating gates. C(CG to FG) is a capacitance between control gate and floating gate and can be defined as:

C(CG to FG)=C(area A)+C(area B)=ε_{A}A(A)/d(D_{A})+ε_{B}A(B)/d(D_{B}) (2),

where ε_{A} is permittivity of material between the upper floating gate 206a and the control gate 202, ε_{B} is permittivity of material between the lower floating gate 206b and the control gate 202, A(A) is an overlap area between the upper floating gate 206a and the control gate 202, A(B) is an overlap area between the lower floating gate 206b and the control gate 202, d(D_{A}) is a separation between the upper floating gate 206a and the control gate 202, and d(D_{B}) is a separation between the lower floating gate 206b and the control gate 202.

When the upper floating gate 206a and the lower floating gate 206b have the same width, the upper floating gate 206a and the lower floating gate 206b are both separated from the control gate 202 by the inter-gate dielectric layer 204, thus ε_{A}=ε_{B}=ε, where ε is permittivity of the inter-gate dielectric layer 204, and D_{A}=D_{B}=D, wherein D is a width of the inter-gate dielectric layer 204.

A variation percentage of the GCR can be referred to as GCR bias, which can be expressed as:

GCR bias=ΔG/G (3),

where ΔG is a difference between GCRs of two memory cells, and G is a value of the GCR of one of the memory cells.

For example, for memory cells 230 and 240, GCR bias can be expressed as:

$$\begin{matrix}GCR bias = C ( area B ) \text{/} C ( area A ) \\ = [ A ( A 240 ) + A ( B 240 ) - A ( A 230 ) ] \text{/} A ( A 230 )\end{matrix} , \qquad ( 4 )$$

where A(A230) is the coupling area between the upper floating gate and the control gate in memory cell 230, and A(A240), A(B240) are the coupling areas between the upper floating gate, the lower floating gate and the control gate in memory cell 240, respectively. If the coupling areas A(A230) and A(A240) covers all the upper floating gates of memory cells 230 and 240, respectively, and the upper floating gates of memory cells 230 and 240 have a substantially same size, A(A230)=A(A240)=A, and Equation (4) becomes:

GCR bias=A(B240)/A(A230)=A(B)/A(A) (5).

Similarly, GCR bias between memory cells 240 and 250 can be expressed as:

GCR bias=[(A(A250)+A(B250))−(A(A240)+A(B240))]/(A(A240)+A(B240)) (6),

where A(A250), A(B250) are the coupling areas between the upper floating gate, the lower floating gate and the control gate in memory cell 250, respectively. If the coupling areas A(A240) and A(A250) covers all the upper floating gates of memory cells 240 and 250, respectively, and the upper floating gates of memory cells 240 and 250 have a substantially same size, A(A240)=A(A250) and the GCR bias=(A(B250)−A(B240))/(A(A240)+A(B240)).

In some implementations, decreasing a variation of the gap heights, e.g., EFHs, between the memory cells in the non-volatile memory device can decrease a difference between the coupling areas to decrease the GCR bias. In some implementations, as discussed with further details below, decreasing a factor ε/d(D) between the memory cells can also decrease the GCR bias, for example, by increasing the separation d(D) between the lower floating gate and the control gate.

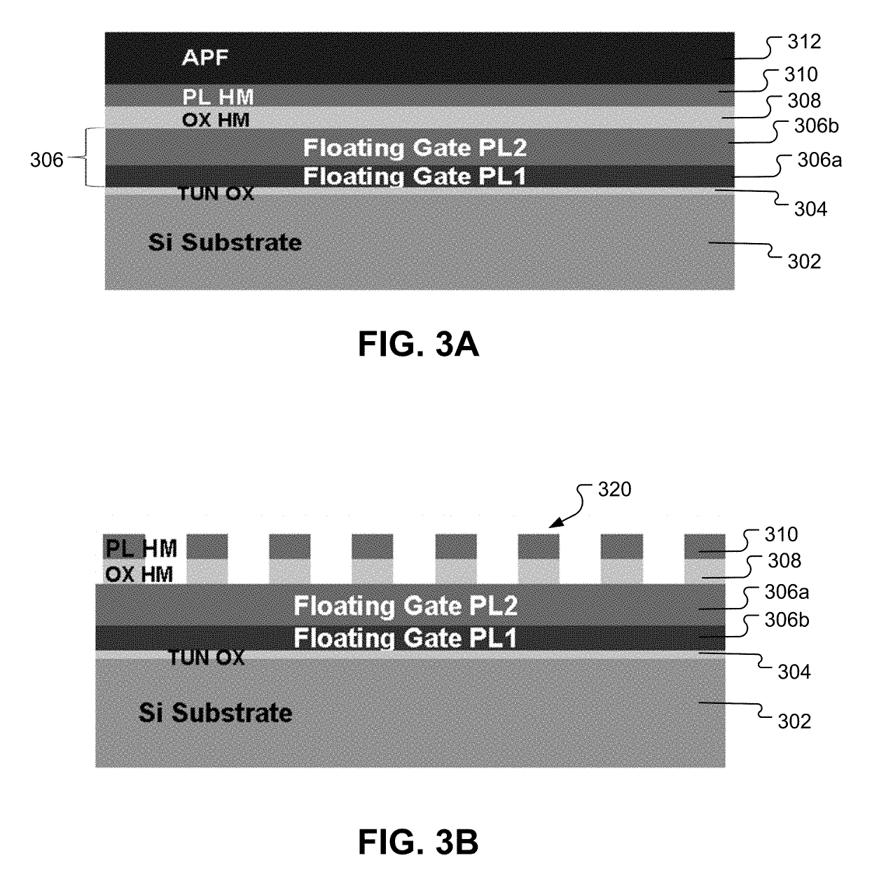

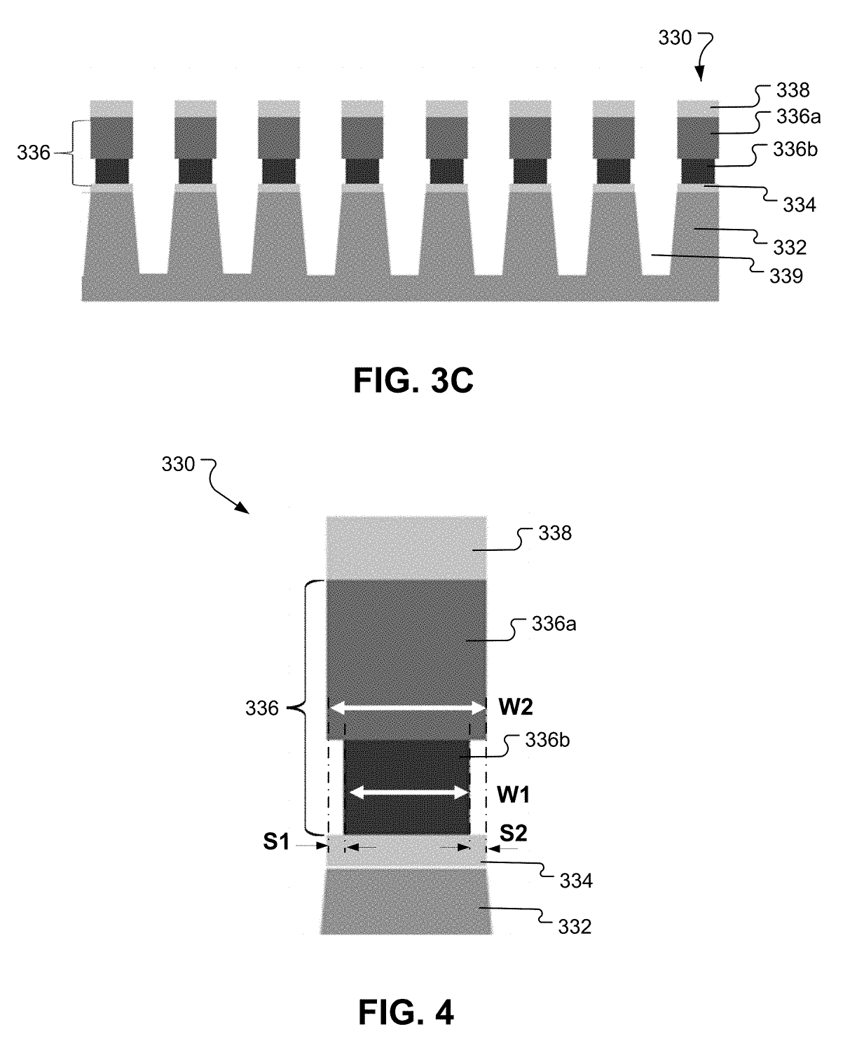

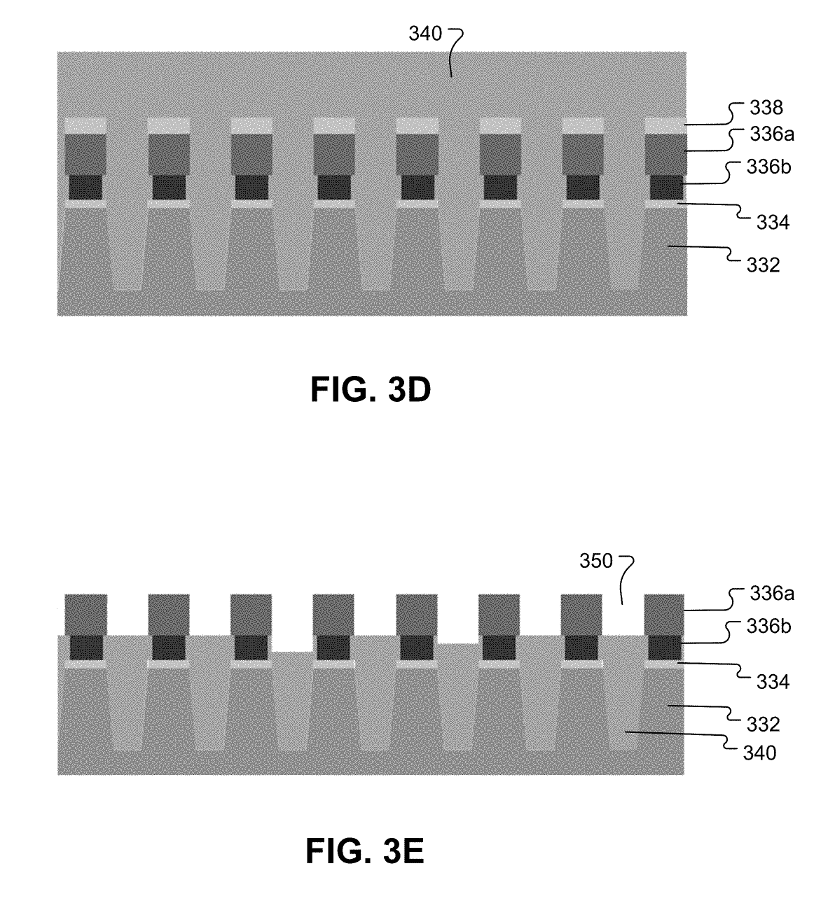

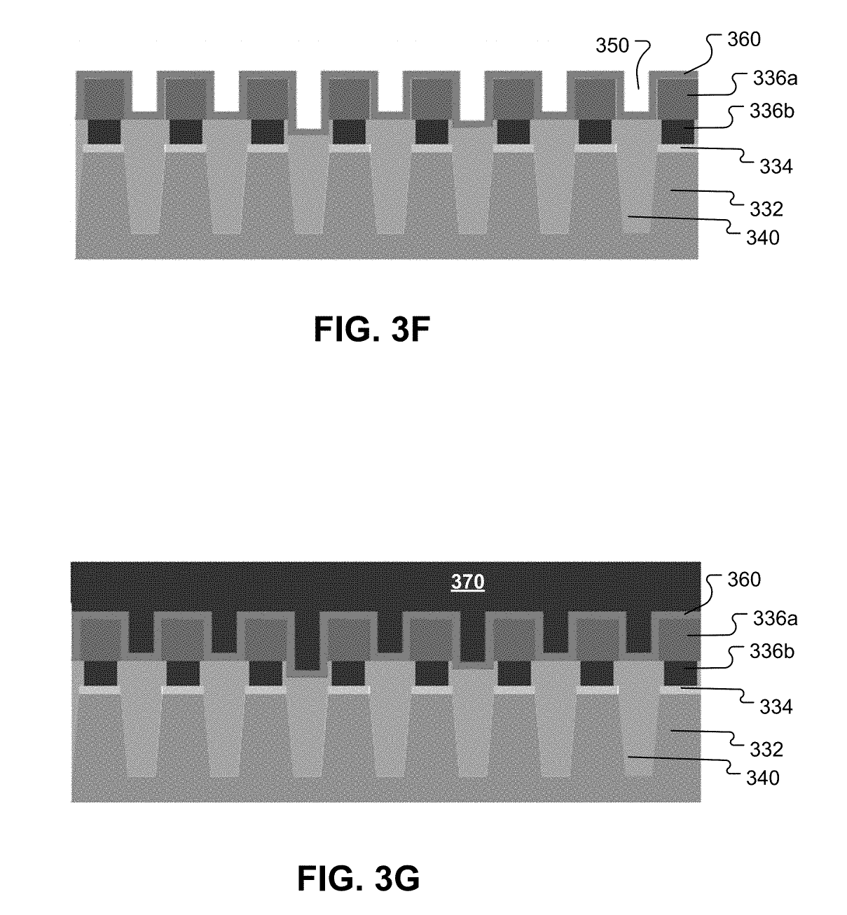

FIGS. 3A-3G are cross-sectional views illustrating process steps of an example method of fabricating a non-volatile memory device. The non-volatile memory device can be the non-volatile memory 116 of FIGS. 1A-1C.

Referring to FIG. 3A, a floating gate layer 306 is provided on a semiconductor substrate 302, e.g., a silicon substrate. The floating gate layer 306 functions as a charge storage layer. The floating gate layer 306 can have a thickness of about 400 to 700 angstrom (Å).

The floating gate layer 306 can include multiple parts, such as an upper floating gate layer 306a and a lower floating gate layer 306b stacked together. The lower floating gate layer 306b can function as a buffer layer to alleviate physical stress and/or gravity pressure on a tunnel insulating layer 304 formed between the floating gate layer 306 and the substrate 302. In some examples, the upper floating gate layer 306a has a thickness of about 50 to 300 Å, and the lower floating gate layer 306b has a thickness of about 300 to 800 Å. In a particular example, the upper floating gate layer 306a has a thickness of about 200 Å, and the lower floating gate layer 306b has a thickness of about 600 Å.

In some implementations, as illustrated in FIG. 3A, the upper floating gate layer 306a and the lower floating gate layer 306b are both made of polysilicon, but the polysilicon of the lower floating gate layer 306b has a smaller grain size than the polysilicon of the upper floating gate layer 306a. The lower floating gate layer 306b and the upper floating gate layer 306a can be formed from metallurgical grade silicon by a chemical purification process. By controlling one or more conditions of the chemical purification process, the formed polysilicon layer as the lower floating gate layer 306b can have a smaller grain size than that of the formed polysilicon layer as the upper floating gate layer 306a.

In a particular example, the lower floating gate layer 306b is made of polysilicon with a grain size less than 10 nm, e.g., within a range between 2 nm and 10 nm. The upper floating gate layer 306a is made of polysilicon with a grain size more than 10 nm, e.g., within a range between 10 nm and 50 nm. As discussed below, polysilicon with a smaller grain size can have a higher etching rate under a particular etching condition.

The tunnel insulating layer 304 can be a tunnel oxidation layer and formed using a thermal oxidation technique. A material of the tunnel insulating layer 304 can include SiO₂ or SiON. The tunnel insulating layer 304 can have a thickness of about 50 to 70 Å.

A mask layer is formed on the upper floating gate layer 306a. The mask layer is used to form a protective pattern for etching the floating gate layer 306, e.g., an etch mask. In some implementations, as illustrated in FIG. 3A, the mask layer can include an oxide (OX) hard mask (HM) layer 308, a polysilicon (PL) hard mask layer 310 (or amorphous silicon HM layer), and an advanced patterning film (APF) 312. In a particular example, the OX HM layer 308, the PL HM layer 310, and the APF 312 can have a thickness of 800 to 1500 Å, 300 to 700 Å, and 800 to 1200 Å, respectively. In some examples, the mask layer can further include a silicon nitride (SiN) HM layer, e.g., as a chemical-mechanical polishing stop layer, between the PL HM layer 310 and the APF 312.

Referring to FIG. 3B, a hard mask pattern 320 for the floating gate layer 306 is formed by etching through the mask layer, e.g., the APF 312, the PL HM layer 310, and OX HM layer 308, and removing the APF 312. The hard mask pattern 320 is the protective pattern for the floating gate layer 306 during etching. A width of each individual hard mask pattern 320 can be related to a width of a memory cell to be fabricated.

Referring to FIG. 3C, the floating gate layer 306 (including the upper floating gate layer 306a and the lower floating gate layer 306b) and the tunnel insulating layer 304 are etched through into the substrate 302 to form a shallow trench isolation (STI) pattern during an etching process. The STI pattern includes a plurality of individual regions 330 each to be fabricated as a memory cell such as a floating gate transistor. The etching process can include dry etching such as reactive ion etching (RIE).

FIG. 4 is a cross-sectional view of a region 330 in FIG. 3C after the etch process. The region 330 includes an active region 332 formed in the substrate 302 and a floating gate 336 on top of the active region 332, a tunnel insulating layer 334 formed from the tunnel insulating layer 304, and a residue oxide HM layer 338 formed from the oxide HM layer 308.

The floating gate 336 includes an upper floating gate 336a formed from the upper floating gate layer 306a and a lower floating gate 336b formed from the lower floating gate layer 306b. As noted above, a material of the lower floating gate layer 306b can have a different property than a material of the upper floating gate layer 306a, e.g., the lower floating gate layer 306b is made of polysilicon with a smaller grain size than the upper floating gate layer 306a. By controlling one or more etching conditions of the etch process, the lower floating gate layer 306b can have a higher etching rate than the upper floating gate layer 306a. For example, the etch process can be controlled by adjusting a flow rate of etching gas, e.g., H—Br or CF4.

Thus, after the etching process, the formed lower floating gate 336b can have a smaller critical dimension (CD) than the formed upper floating gate 336a. For example, a width W1 of the lower floating gate is smaller than a width W2 of the upper floating gate 336a, that is, W1<W2. Since opposing walls of the lower floating gate 336b are etched under the same etching condition in the same etching process, a shrinkage S1 on the left side of the lower floating gate 336b can be substantially identical to a shrinkage S2 on the right side of the lower floating gate 336b, e.g., S1=S2. The shrinkage S1 is defined as a horizontal distance between adjacent sidewalls of the upper floating gate 336a and the lower floating gate 336b on the left side. The shrinkage S2 is defined as a horizontal distance between adjacent sidewalls of the upper floating gate 336a and the lower floating gate 336b on the right side.

Also since the upper floating gate 336a, the lower floating 336b and the active region 332 are formed in the same etching process, the lower floating gate 336b and the upper floating gate 336a are self-aligned with the active region 332. The lower floating gate 336b and the upper floating gate 336a can have a same center line.

Referring back to FIG. 3C, adjacent active regions 332 define trenches 339 therebetween. The trenches 339 can have a rectangular shape, a “V” shape, a “U” shape, or any suitable shape. For illustration only, in FIG. 3C, the trenches 339 has a trapezoid shape with a width increasing from a bottom surface to a top surface along the sidewalls of the active regions 332. The trenches connect to gaps between the sidewalls of adjacent floating gates.

Referring to FIG. 3D, an isolation layer 340 is formed on top of the regions 330 and in the gaps and the trenches 339. Particularly, as illustrated in FIG. 3D, a material of the isolation layer 340 fills in gaps between adjacent lower floating gates 336b. Due to the shrinkage of the lower floating gate 336b with respect to the upper floating gate 336a, the material of the isolation layer 340 fills adjacent sidewalls of the lower floating gate 336b and under the upper floating gate 336a. As discussed below, the material of the isolation layer 340 can affect the GCR bias. In some examples, the isolation layer 340 can include spin-on dielectric (SOD) or any other material having high fill-in ability and high dielectric property.

Referring to FIG. 3E, the isolation layer 340 is etched to form gaps 350 between adjacent floating gates, e.g., by SiCoNi etching or other high selective anisotropic etching tool. In some cases, a top surface of the remaining isolation layer 340 (or bottom surfaces of the gaps 350) can be at a substantially same level as a bottom surface of the upper floating gate 336a (or a top surface of the lower floating gate 336b). In some cases, the top surface of the remaining isolation layer 340 can be between the top surface and the bottom surface of the lower floating gate 336b. The bottom surfaces of the gaps 350 may vary, and there may be a variation of EFH for the gaps 350, e.g., due to the etching process.

Referring to FIGS. 3F and 3G, an inter-gate dielectric layer 360 and a control gate layer 370 are sequentially formed on the floating gates 336 and in the gaps 350. The inter-gate dielectric layer 360 is configured to separate the floating gates 336 and the control gate layer 370. The inter-gate dielectric layer 360 can be an inter poly dielectric (IPD) layer and can be form by depositing OX/SiN/OX(ONO) film, SiN/OX/SiN/OX/SiN(NONON) film, or any other high-k (or high dielectric constant) dielectric film. The control gate layer 370 can be formed by depositing polysilicon with small grain sizes by furnace, e.g., for better filling into the gaps. In some cases, the control gate layer 370 includes a doped polysilicon layer and/or a polycide layer.

As shown in FIG. 3G, when a bottom surface of the inter-gate dielectric layer 360 is below the upper surface of the lower floating gate 336b, there exists the material of the isolation layer 340 between adjacent sidewalls of the lower floating gate 336b and the inter-gate dielectric layer 360. That is, the lower floating gate 336b and the control gate layer 370 are separated by the material of the isolation layer 340 and the inter-gate dielectric layer 360, which can be used to decrease coupling between the floating gate 336 and the control gate layer 370, as discussed below.

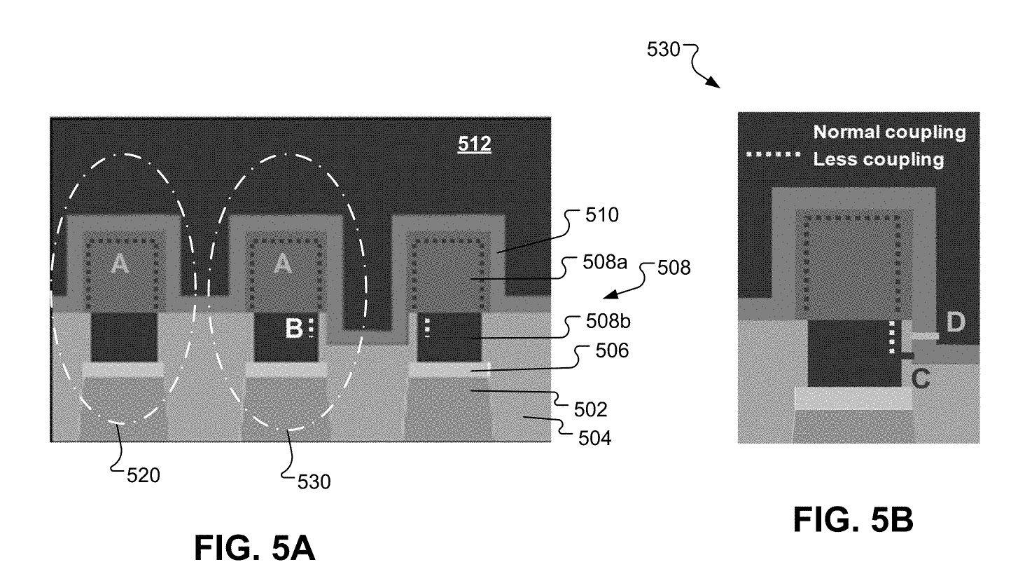

FIGS. 5A-5B are cross-sectional views of an example non-volatile memory device illustrating example coupling between floating gate and control gate. The memory device can be the memory device shown in FIG. 3G. The memory device can include a number of individual memory cells including memory cell 520 and memory cell 530. Each memory cell can include an active region 502, an isolation layer 504, a tunnel insulating layer 506, a floating gate 508 including a lower floating gate 508b and an upper floating gate 508a, an inter-gate dielectric layer 510, and a control gate 512.

When a bottom surface of the inter-gate dielectric layer 510 is higher than or at the same level as a bottom surface of the upper floating gate 508a, e.g., in memory cell 520, coupling between the floating gate 508 and the control gate occurs at an overlap area A between the upper floating gate 508a and the control gate 512, which is similar to the coupling in memory cell 230 in FIG. 2.

When a bottom surface of the inter-gate dielectric layer 510 is lower than the bottom surface of the upper floating gate 508a (or a top surface of the lower floating gate 508b), e.g., in memory cell 530, coupling between the floating gate 508 and the control gate 512 occurs at an overlap area A between the upper floating gate 508a and the control gate 512 and an overlap area B between the lower floating gate 508b and the control gate 512. However, the coupling between the lower floating gate 508b and the control gate 512 in FIGS. 5A-5B is different from the coupling between the lower floating gate 206b and the control gate 202 in FIG. 2.

According to Equation (2) above, a capacitance between the floating gate 508 and the control gate 512 in memory cell 530 can be expressed as:

C(CG to FG)=C(area A)+C(area B)=ε_{A}A(A)/D+ε_{B}A(B)/(D+C) (7),

where ε_{A} is permittivity of the inter-gate dielectric layer 510, ε_{B} is effective permittivity of material between the lower floating gate 508b and the control gate 512, A(A) is an overlap area between the upper floating gate 508a and the control gate 512, A(B) is an overlap area between the lower floating gate 508b and the control gate 512, D is a width of the inter-gate dielectric layer 510, and C is a width of the isolation layer 504 between sidewalls of the lower floating gate 508b and the inter-gate dielectric layer 510.

Accordingly, GCR bias between memory cells 520 and 530 can be expressed as:

GCR bias=(ε_{B}/ε_{A})*(D/(D+C))*(A(B)/A(A)) (8).

If the inter-gate dielectric layer 510 and the isolation layer 504 have substantially same permittivity, ε_{B}/ε_{A}≈1. Compared to GCR bias between memory cells 230 and 240, as shown in Equation (4), the GCR bias between memory cells 520 and 530 is smaller. And there is less gate coupling in memory cell 530 than memory cell 240 due to the increased width between the lower floating gate 508b and the inter-gate dielectric layer 510.

From Equation 8, it is shown that the GCR bias can be decreased by decreasing ε_{B}/ε_{A}. In some cases, the inter-gate dielectric layer 510 can include material with higher permittivity and the isolation layer can include material with lower permittivity. Also, the GCR bias can be decreased by decreasing D/(D+C). In some cases, the shrinkage of the lower floating gate 508b with respect to the upper floating gate 508a can be increased, such that the width C can be increased. In some cases, the width of the inter-gate dielectric layer D can be decreased to decrease the GCR bias. The methods in the cases above can be also in any suitable combination to decrease the GCR bias.

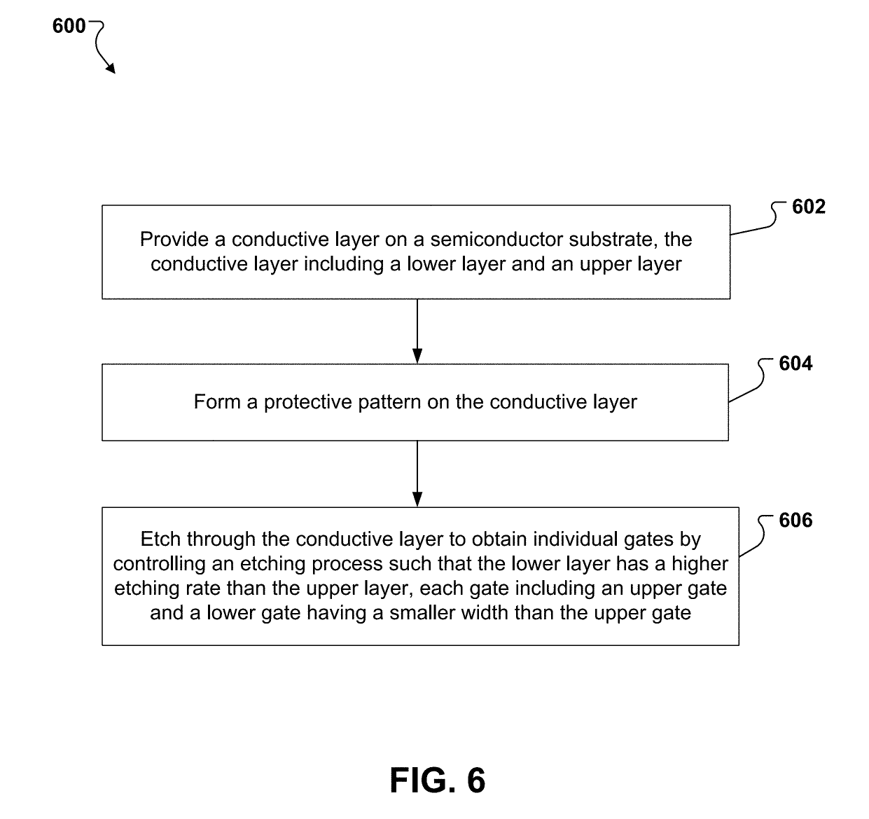

FIG. 6 shows an example process of fabricating a semiconductor device, according to one or more implementations. The semiconductor device can be the non-volatile memory 116 of FIGS. 1A-1C. The process can include one or more process steps of the method shown in FIGS. 3A-3G.

A conductive layer is provided on a semiconductor substrate (602). The conductive layer includes a lower conductive layer and an upper conductive layer that are sequentially stacked. Particularly, the lower conductive layer includes a first material and the upper conductive layer includes a second material having at least one property different from the first material. The lower conductive layer and the upper conductive layer can be made of polysilicon and the lower conductive layer can have a smaller grain size than the upper conductive layer, such that the lower conductive layer can have a higher etching rate than the upper conductive layer during an etching process. In a particular example, the first material includes polysilicon with a grain size less than 10 nm, and the second material includes polysilicon with a grain size in a range between 10 nm and 50 nm.

In some examples, providing the conductive layer on the semiconductor substrate includes forming a tunnel insulating layer on the semiconductor substrate. The tunnel insulating layer can be a tunnel oxide layer.

A protective pattern is formed on the conductive layer (604). In some examples, forming the protective pattern on the conductive layer includes forming one or more layers, e.g., OX HM, PL HM, and APF, as a hard mask on the conductive layer, as illustrated in FIG. 3A. Then the hard mask layers are patterned, e.g., by photolithography, and etched, e.g., by dry etching and/or wet etching, to obtain a hard mask pattern as the protective pattern for the conductive layer, e.g., as illustrated as FIG. 3B. In some examples, forming the protective pattern on the conductive layer can use self-aligned double patterning (SADP) technique.

The conductive layer is etched through to obtain individual separated gates (606), e.g., as illustrated in FIG. 3C. The gates can be used as floating gates. Each gate can include an upper gate formed from the upper conductive layer and a lower gate formed from the lower conductive layer. The etching can be implemented by controlling an etching process such that the first material has a higher etching rate than the second material during the etching process. In such a way, the lower conductive layer can be etched more than the upper conductive layer, and the lower gate can have a smaller width than the upper gate after the etching process. The lower gate and the upper gate can have a same center line. In some cases, a distance between sidewalls of the lower gate and the upper gate on the left side can be substantially identical to a distance between sidewalls of the lower gate and the upper gate on the right side.

In some cases, controlling the etching process includes controlling a flow rate of etching gas during the etching process. In some cases, the etching process is part of a shallow trench isolation (STI) etch process for the conductive layer.

In some cases, controlling the etching process to etch the conductive layer includes etching the conductive layer through into the semiconductor substrate to form trenches between adjacent gates. Then the process can further include forming an isolation layer on the protective pattern and in the trenches, a material of the isolation layer being filled in the trenches, e.g., as illustrated in FIG. 3D. The material of the isolation layer can include spin-on dielectric (SOD) material. Then the isolation layer is etched to obtain gaps between adjacent gates, as illustrated in FIG. 3E. At least one of the gaps has a bottom surface between lower surfaces of an upper gate and a lower gate of one of the individual gates.

When a dielectric layer is formed on the gates and the isolation layer in the gaps, a space between sidewalls of the lower gate of the one of the individual gates and the dielectric layer is filled with the material of the isolation layer, e.g., as illustrated in FIG. 3F. Then a second conductive layer can be formed as a second gate electrode on the dielectric layer, as illustrated in FIG. 3H.

As separation between the second gate electrode and the lower gate is increased by the filled-in material of the isolation layer between sidewalls of the lower gate and the dielectric layer, coupling between the individual gate and the second gate electrode can be decreased. This decrease can reduce non-uniformity of GCR due to a variation of EFH in the gaps between adjacent gates.

In some implementations, the individual gates can be used as floating gates, and the second gate electrode can be used as a control gate electrode. Source/drain regions can be formed in an active region under a floating gate in the semiconductor substrate. Thus, floating gate transistors can be formed. The floating gate transistors can be used as memory cells of a non-volatile memory device. Other components and periphery can be also formed on the semiconductor substrate to form the non-volatile memory device.

While this document may describe many specifics, these should not be construed as limitations on the scope of an invention that is claimed or of what may be claimed, but rather as descriptions of features specific to particular embodiments. Certain features that are described in this document in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination in some cases can be excised from the combination, and the claimed combination may be directed to a sub-combination or a variation of a sub-combination. Similarly, while operations are depicted in the drawings in a particular order, this should not be understood as requiring that such operations be performed in the particular order shown or in sequential order, or that all illustrated operations be performed, to achieve desirable results.

Only a few examples and implementations are disclosed. Variations, modifications, and enhancements to the described examples and implementations and other implementations can be made based on what is disclosed.

What is claimed is:

1. A method of fabricating a semiconductor device, the method comprising:
providing a conductive layer on a semiconductor substrate, the conductive layer comprising a lower conductive layer and an upper conductive layer, the lower conductive layer including a first material and the upper conductive layer including a second material having at least one property different from the first material;
forming a protective pattern on the conductive layer; and
etching through the conductive layer to obtain individual separated gates by controlling an etching process such that the first material has a higher etching rate than the second material during the etching process, each of the gates including an upper gate and a lower gate, the lower gate having a smaller width than the upper gate after the etching process.

2. The method of claim 1, wherein the lower gate and the upper gate have a same center line.

3. The method of claim 1, wherein the first material has a smaller grain size than the second material.

4. The method of claim 3, wherein the first material comprises polysilicon with a grain size less than 10 nm, and the second material comprises polysilicon with a grain size in a range between 10 nm and 50 nm.

5. The method of claim 1, wherein controlling the etching process comprises controlling a flow rate of etching gas.

6. The method of claim 1, wherein the etching process is part of a shallow trench isolation (STI) etching process for fabricating the semiconductor device.

7. The method of claim 1, wherein providing the conductive layer on the semiconductor substrate comprises:
forming a tunnel insulating layer on the semiconductor substrate

8. The method of claim 1, wherein forming the protective pattern on the conductive layer comprises:
forming one or more layers as a hard mask on the conductive layer;
forming a second protective pattern on the one or more layers; and
etching through the one or more layers to obtain a hard mask pattern as the protective pattern for the conductive layer.

9. The method of claim 1, wherein forming the protective pattern on the conductive layer comprises using self-aligned double patterning (SADP).

10. The method of claim 1, wherein controlling the etching process to etch the conductive layer comprises:
etching through the conductive layer into the semiconductor substrate to form trenches between adjacent gates.

11. The method of claim 10, further comprising:
forming an isolation layer on the protective pattern and in the trenches.

12. The method of claim 11, wherein a material of the isolation layer comprises spin-on dielectric (SOD) material.

13. The method of claim 11, further comprising etching the isolation layer to obtain gaps between adjacent gates of the individual gates,
wherein at least one of the gaps has a bottom surface between lower surfaces of an upper gate and a lower gate of one of the individual gates.

14. The method of claim 13, further comprising:
forming a dielectric layer on the individual gates and the isolation layer in the gaps, wherein a space between sidewalls of the lower gate of the one of the individual gates and the dielectric layer is filled with the isolation layer.

15. The method of claim 14, further comprising:
forming a second conductive layer on the dielectric layer as a second gate electrode.

16. A semiconductor memory device comprising:
a semiconductor substrate including active regions protruding therefrom, adjacent active regions defining trenches therebetween;
an isolation layer formed on the semiconductor substrate and in the trenches;
floating gates formed on corresponding active regions, each floating gate having a lower floating gate and an upper floating gate that are sequentially stacked, the lower floating gate having a smaller width than the upper floating gate and a substantially same center line as the upper floating gate;
an inter-gate dielectric layer on top surfaces of the floating gates and on the isolation layer, the inter-gate dielectric layer defining gaps between adjacent floating gates, and
a control gate electrode on top of the floating gates and in the gaps of the dielectric layer,
wherein at least one of the gaps has a bottom surface being between a top surface and a bottom surface of the lower floating gate of one of the floating gates, and a space between sidewalls of the lower floating gate and the inter-gate dielectric layer in the gap is filled with a material of the isolation layer.

17. The semiconductor memory device of claim 16, wherein the lower floating gate and the upper floating gate of each of the floating gates are self-aligned with the corresponding active region.

18. The semiconductor memory device of claim 16, wherein a gate coupling ratio between the one of the floating gates and the control gate electrode is partially based on a width of the filled-in material of the isolation layer in the space.

19. The semiconductor memory device of claim 16, further comprising a tunnel insulating layer positioned between each of the floating gates and the corresponding active region.

20. A method of fabricating a semiconductor device, the method comprising:
providing a physical layer on a semiconductor substrate, the layer having a lower layer and an upper layer that are sequentially stacked, the lower layer including a first material and the upper layer including a second material that has at least one property different from the first material;
forming a protective pattern on the layer; and
controlling an etching process to etch the layer, such that the first material has a different etching rate than the second material during the etching process and the lower layer has a different dimension than the upper layer after the etching process, the lower layer and the upper layer having a same center line.
